(19) United States
(12) Patent Application Publication
(10) Pub. No.: US 2011/0254170 A1
(43) Pub. Date: Oct. 20, 2011

(54) SEMICONDUCTOR DEVICE

(75) Inventor: Kenichi Ishii, Ome-shi (JP)

(73) Assignee: Kabushiki Kaisha Toshiba, Tokyo (JP)

(21) Appl. No.: 13/039,975

(22) Filed: Mar. 3, 2011

(30) Foreign Application Priority Data
Apr. 15, 2010 (JP) 2010-094186

(51) Int. Cl. H01L 23/48

(52) U.S. Cl. 257/774; 257/E23.011

(57) ABSTRACT

According to one embodiment, a semiconductor device includes a base layer on which a revision signal transmission circuit is formed, three or more interconnect layers laminated on the base layer, a power source interconnect or a ground interconnect on an uppermost interconnect layer, and a revision signal line which connects the revision control circuit only to the power source interconnect or the ground interconnect of the uppermost interconnect layer.

### CROSS-REFERENCE TO RELATED APPLICATIONS

This application is based upon and claims the benefit of priority from Japanese Patent Application No. 2010-094186, filed Apr. 15, 2010; the entire contents of which are incorporated herein by reference.

### FIELD

Embodiments described herein relate generally to a semiconductor device including a revision ID control circuit.

### BACKGROUND

As a semiconductor device, for example, a system-on-a-chip (SOC) includes a base layer and a plurality of interconnect layers sequentially laminated on the base layer via insulating layers. A revision ID control circuit, which transmits a revision ID signal that identifies an SOC, is formed on the base layer. Further, each of the interconnect layers is formed with a plurality of signal lines, ground interconnects, and the like.

In a wafer manufacturing process of the SOC, after the base layer is formed, the interconnect layers are made by being sequentially overlapped with the insulating layers and the like sandwiched therebetween. In a process of manufacture, although the interconnects of the interconnect layers may be changed to correct a function of the SOC, an revision ID is changed together in many cases to identify an SOC before it is changed from the SOC after it is changed.

The revision ID control circuit is ordinarily connected to an interconnect of an interconnect layer, which is as close to the base layer as possible, of the interconnect layers. Accordingly, when it becomes necessary to correct the function in the manufacturing process of the SOC and, for example, a second interconnect layer is changed, there is a case in which a revision ID can be changed only in a first interconnect layer. In the case, a semi-finished product in the manufacturing process, in which the first interconnect layer before the revision ID is changed is formed, is discarded because the revision ID thereof cannot be changed. When the function is corrected in the manufacturing process, since it is necessary to remake the interconnect layers from the first interconnect layer, it is time-consuming to manufacture the interconnect layers.

In view of the above problem, it is desired to provide a semiconductor device which can be promptly manufactured even when the function is corrected as well as can reduce an amount of discarded semi-finished products.

### BRIEF DESCRIPTION OF THE DRAWINGS

A general architecture that implements the various feature of the embodiments will now be described with reference to the drawings. The drawings and the associated descriptions are provided to illustrate the embodiments and not to limit the scope of the invention.

FIG. 1 is an exemplary exploded perspective view of an SOC according to a first embodiment;

FIG. 2 is an exemplary sectional view of the SOC according to the first embodiment;

FIG. 3 is an exemplary exploded perspective view of an SOC according to a second embodiment; and

FIG. 4 is an exemplary exploded perspective view showing an SOC after correction in the second embodiment.

### DETAILED DESCRIPTION

Various embodiments will be described hereinafter with reference to the accompanying drawings.

In general, according to one embodiment, a semiconductor device comprises a base layer on which a revision signal transmission circuit is formed; three or more interconnect layers laminated on the base layer; a power source interconnect or a ground interconnect on an uppermost interconnect layer; and a revision signal line which connects the revision control circuit only to the power source interconnect or the ground interconnect of the uppermost interconnect layer.

Semiconductor devices according to embodiments will be described below in detail referring to the drawings.

### First Embodiment

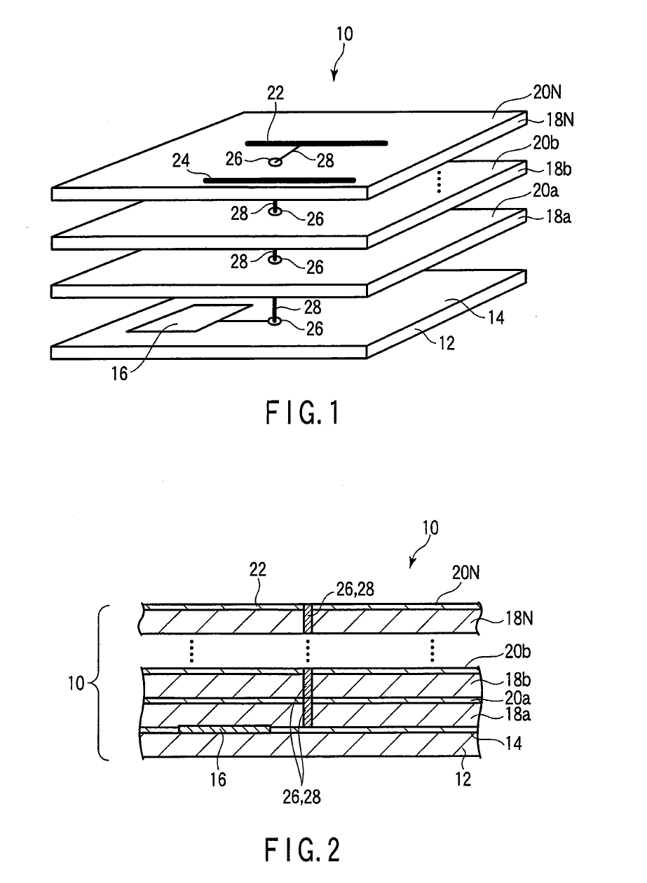

FIGS. 1 and 2 are an exploded perspective view and a sectional view showing an SOC (system-on-a-chip) as a semiconductor device according to a first embodiment.

As shown in FIGS. 1 and 2, an SOC 10 includes a base layer 14 formed on an insulating substrate 12, and the base layer 14 is formed with a revision ID control circuit (revision signal transmission circuit) 16 that transmits a revision ID signal which identifies the SOC 10. The SOC 10 includes a plurality of layers, for example, three or more interconnect layers sequentially laminated on the base layer 14 via insulating layers. In this embodiment, the SOC 10 includes a first interconnect layer 20a laminated on the base layer 14 via an insulating layer 18a, a second interconnect layer 20b laminated on the first interconnect layer 20a via an insulating layer 18b, a plurality of interconnect layers laminated on the second interconnect layer 20b via insulating layers, respectively, and an uppermost interconnect layer 20N laminated via an insulating layer 18N.

Each of the interconnect layers 20a to 20N is formed with a plurality of signal lines, ground interconnects, and the like. The uppermost interconnect layer 20N is formed with at least a power source interconnect 22 and a ground interconnect 24. Each layer from the second insulating layer 18a to the uppermost interconnect layer 20N is formed with a through-hole 26, and the through-holes are arranged in a line and electrically conductive with each other. The revision ID control circuit 16 is connected only to the power source interconnect 22 of the uppermost interconnect layer 20N via the through-holes 26 which configure a revision signal line 28. More specifically, a revision ID, which is transmitted from the revision ID control circuit 16, passes through the insulating layers 18a, 18b, the first interconnect layer 20a, the second interconnect layer 20b, . . . , the uppermost insulating layer 18N, and the interconnect layer 20N from the base layer 14, and a signal is lifted up to the power source interconnect 22 of the uppermost interconnect layer 20N.

Connection of the revision signal line 28 to the power source interconnect 22 on the uppermost interconnect layer 20N sets the revision ID signal to “1”. In a wafer manufacturing process of the SOC 10, after the base layer 14 is formed, the SOC 10 is manufactured by sequentially overlapping the interconnect layers 20a, 20b, . . . , 20N with the insulating layers 18a, 18b . . . , 18N sandwiched therebetween.

In the manufacturing process, when, for example, the second interconnect layer 20b is changed by correcting a function of the SOC 10, the revision ID is changed together to discriminate SOCs before the second interconnect layer 20b is changed and after it is changed. When the value of the revision ID signal is changed by the correction of the function of the SOC 10, the revision signal line 28, which is connected to the power source interconnect 22 on the uppermost interconnect layer 20N, is removed, and the revision signal line 28 is connected to the ground interconnect 24. With the operation, the value of the revision ID is changed to “0”.

As described above, according to the SOC 10, the value of the revision ID signal can be changed only by the change of the uppermost interconnect layer 20N. Accordingly, the SOC after the change can be manufactured using a semi-finished product in which the first interconnect layer 20a is formed before the second interconnect layer 20b, which is changed by the correction of the function of the SOC, is formed. With the configuration, the SOC can be manufactured promptly after the revision ID is changed and further an amount of semi-finished products which are discarded because they cannot be applied to the SOCs after the change can be reduced.

### Second Embodiment

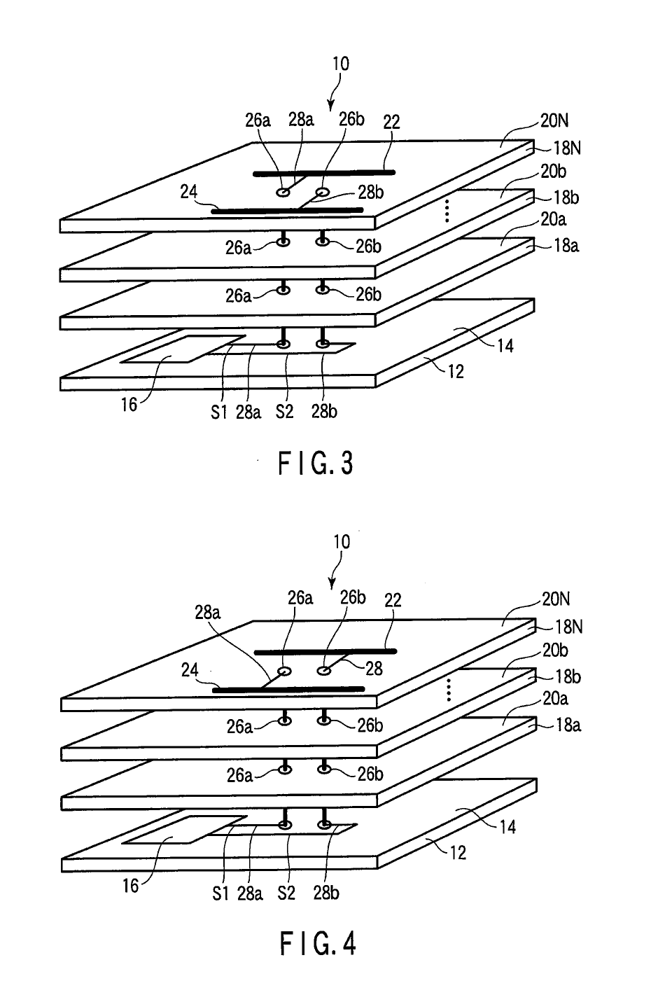

FIGS. 3 and 4 are exploded perspective views showing an SOC (system-on-a-chip) as a semiconductor device according to a second embodiment. Plural bits are used as a revision ID of an SOC 10 in many cases, and, according to the second embodiment, the revision ID is set to 2 bits.

As shown in FIG. 3, the SOC 10 includes a base layer 14 formed on an insulating substrate 12, and the base layer 14 is formed with a revision ID control circuit (revision signal transmission circuit) 16 which transmits a 2-bit revision ID signal that identifies the SOC 10. The SOC 10 includes a plurality of layers, for example, three or more interconnect layers sequentially laminated on the base layer 14 via insulating layers. In the embodiment, the SOC 10 includes a first interconnect layer 20a laminated on the base layer 14 via an insulating layer 18a, a second interconnect layer 20b laminated on the first interconnect layer 20a via an insulating layer 18b, a plurality of interconnect layers laminated on the second interconnect layer 20b via insulating layers, respectively, and an uppermost interconnect layer 20N laminated via an insulating layer 18N.

Each of the interconnect layers 20a to 20N is formed with a plurality of signal lines, ground interconnects, and the like. The uppermost interconnect layer 20N is formed with at least a power source interconnect 22 and a ground interconnect 24. The revision ID control circuit 16 is connected to the power source interconnect 22 of the uppermost interconnect layer 20N by a first revision signal line 28a and further connected to the ground interconnect 24 of the uppermost interconnect layer 20N by a second revision signal line 28b.

Each layer from the second insulating layer 18a to the uppermost interconnect layer 20N is formed with a through-hole 26a, and the through-holes 26a are arranged in a line and electrically conductive with each other. The through-holes 26a configure the first revision signal line 28a. Each layer from the second insulating layer 18a to the uppermost interconnect layer 20N is formed with a through-hole 26b, and the through-holes 26b are arranged in a line and electrically conductive with each other. The through-holes 26b configure the second revision signal line 28b.

A revision ID, which is transmitted from the revision ID control circuit 16, passes through the insulating layers 18a, 18b, the first interconnect layer 20a, the second interconnect layer 20b, . . . , the uppermost insulating layer 18N, and the interconnect layer 20N from the base layer 14, and a signal is lifted up to the power source interconnect 22 and the ground interconnect 24 of the uppermost interconnect layer 20N.

The first revision signal line 28a is connected to the power source interconnect 22 and the second revision signal line 28b is connected to the ground interconnect 24 on the uppermost interconnect layer 20N, respectively so that the 2-bit revision ID becomes bit [1:0]=2′b01. The revision ID control circuit 16 of the SOC 10 is divided to a revision ID bit [0] signal S1 and a revision ID bit [1] signal S2.

In a manufacturing process, when, for example, an interconnect of the second interconnect layer 20b is changed by correcting a function of the SOC 10, the revision ID is changed together to discriminate an SOC before it is changed from the SOC after it is changed. When bit [1:0] of the revision ID is changed from 2′b01 to 2′b10, it is necessary to change the signal lines 28a, 28b of the two revision ID signals. According to the embodiment, as shown in FIG. 4, the first revision signal line 28a, which is connected to the power source interconnect 22, and the second revision signal line 28b, which is connected to the ground interconnect 24, on the uppermost interconnect layer 20N, respectively are removed, and the first revision signal line 28a is connected to the ground interconnect 24 and the second revision signal line 28b is connected to the power source interconnect 22. With the operation, the value of the revision ID is changed to bit [1:0]=2′b10.

As described above, according to the SOC 10, the value of the revision ID signal can be changed only by the change of the uppermost interconnect layer 20N. Accordingly, the SOC after the change can be manufactured using a semi-finished product in which the first interconnect layer 20a is formed before the second interconnect layer 20b, which is changed by the correction of the function of the SOC, is formed.

When, for example, an interconnect layer, which can be used when the revision ID is changed from 0 (2′b00) to 1 (2′b01) and further changed by the correction of the function of the SOC 10, is the same as the second interconnect layer 20b, the lowermost interconnect layer 20a whose change is necessary is the same layer. However, when the value of the revision ID is changed from 1 (2′b01) to 2 (2′b10) at the time the change is made again, a conventional method needs to restore the changed revision ID of the second interconnect layer 20b in order to restore the value of bit [0]. In this embodiment, the value of the revision ID can be arbitrarily changed only by the change of the uppermost interconnect layer 20N.

With the configuration, the SOC can be manufactured promptly after the revision ID is changed and further an amount of semi-finished products which are discarded because they cannot be applied to the SOCs after the change can be reduced.

According to the first and second embodiments, there can be provided a semiconductor device which can prevent a delay of a manufacturing period resulting from the change of the revision ID which is made due to the correction of the function and can reduce a loss generated by the change in the manufacturing process.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, the semiconductor device may be applied not only to the SOC but also to other semiconductor devices. The number of bits of the revision ID signal can be increased as necessary, in which case it is only necessary to increase the number of the revision signal lines in response to the number of the bits.

What is claimed is:

1. A semiconductor device comprising:
a base layer on which a revision signal transmission circuit is formed;
three or more interconnect layers laminated on the base layer;
a power source interconnect or a ground interconnect on an uppermost interconnect layer; and
a revision signal line which connects the revision control circuit only to the power source interconnect or the ground interconnect of the uppermost interconnect layer.

2. The semiconductor device of claim 1, wherein the revision signal line is connected to the power source interconnect of the uppermost interconnect layer.

3. The semiconductor device of claim 1, wherein the revision signal line comprises a first revision signal line and a second revision signal line connected to the revision signal transmission circuit, the first revision signal line is connected to the power source interconnect of the uppermost interconnect layer, and the second revision signal line is connected to the ground interconnect of the uppermost interconnect layer.

4. The semiconductor device of claim 1, wherein the revision signal line comprises a first revision signal line and a second revision signal line connected to the revision signal transmission circuit, the first revision signal line is connected to the ground interconnect of the uppermost interconnect layer, and the second revision signal line is connected to the power source interconnect of the uppermost interconnect layer.

5. The semiconductor device of claim 1, further comprising through-holes formed in the respective interconnect layers and conductive with each other to form a part of the revision signal line.

6. The semiconductor device of claim 2, further comprising through-holes formed in the respective interconnect layers and conductive with each other to form a part of the revision signal line.

7. The semiconductor device of claim 3, further comprising through-holes formed in the respective interconnect layers and conductive with each other to form a part of the revision signal line.
